(19) United States
(12) Patent Application Publication
(10) Pub. No.: US 2024/0351163 A1
(43) Pub. Date: Oct. 24, 2024

(54) POLISHING METHOD, POLISHING APPARATUS, AND COMPUTER-READABLE STORAGE MEDIUM STORING TEMPERATURE REGULATION PROGRAM

(71) Applicant: EBARA CORPORATION, Tokyo (JP)

(72) Inventors: Masayoshi ITO, Tokyo (JP); Seungho YUN, Tokyo (JP); Yukihiro KANG, Tokyo (JP); Yasuyuki MOTOSHIMA, Tokyo (JP); Shumpei MIURA, Tokyo (JP); Kenichi SUZUKI, Tokyo (JP)

(21) Appl. No.: 18/634,676

(22) Filed: Apr. 12, 2024

(30) Foreign Application Priority Data
Apr. 21, 2023 (JP) 2023-069920

(51) Int. Cl. B24B 49/14; B24B 49/04; B24B 49/16

(52) U.S. Cl. CPC B24B 49/14; B24B 49/04; B24B 49/16

(57) ABSTRACT

A polishing method capable of appropriately controlling a temperature of a polishing surface of a polishing pad during polishing of a workpiece is disclosed. The polishing method includes detecting a surface condition of a sample while polishing the sample on a polishing surface of a polishing pad; creating time-series data representing temporal change in the surface condition of the sample; determining a point in time at which the surface condition of the sample has distinctively changed based on the time-series data; determining a temperature control time based on the determined point in time; and controlling a temperature of the polishing surface of the polishing pad based on the temperature control time, while polishing a workpiece on the polishing surface of the polishing pad.

### CROSS REFERENCE TO RELATED APPLICATION

This document claims priority to Japanese Patent Application No. 2023-069920 filed Apr. 21, 2023, the entire contents of which are hereby incorporated by reference.

### BACKGROUND

A CMP (Chemical Mechanical Polishing) apparatus is used in a process of polishing a surface of a wafer in manufacturing of semiconductor devices. The CMP apparatus is configured to rotate a wafer having a film by a polishing head, and press the wafer against a polishing pad on a rotating polishing table with the polishing head to thereby polish the film that forms a surface of the wafer. During polishing of the wafer, a polishing liquid (slurry) is supplied onto the polishing pad. The film of the wafer is planarized by a chemical action of the polishing liquid and mechanical action(s) of abrasive grains contained in the polishing liquid and/or the polishing pad.

A polishing rate of the wafer depends not only on a polishing load on the wafer pressed against the polishing pad, but also on a surface temperature of the polishing pad. This is because the chemical action of the polishing liquid on the film of the wafer depends on the temperature. Therefore, in the manufacturing of semiconductor devices, it is important to optimize the surface temperature of the polishing pad during polishing of the wafer in order to achieve an appropriate polishing rate of the film.

From this viewpoint, a pad-temperature regulating device for regulating the surface temperature of the polishing pad is conventionally used (for example, see Japanese laid-open patent publication No. 2017-148933). The pad-temperature regulating device has a pad contact member into which temperature-controlled heating liquid and cooling liquid are supplied. A flow rate of the heating liquid and a flow rate of the cooling liquid supplied to the pad contact member are regulated, so that the surface temperature of the polishing pad during polishing of the wafer can be maintained at a desired temperature.

A wafer generally has a multilayered structure including a plurality of films. A film to be polished of the wafer is the uppermost film of the plurality of films forming the multilayered structure. As the wafer is polished, the uppermost film is removed, so that a lower film underlying the uppermost film is exposed. Therefore, the lower film comes into contact with the polishing pad and is polished. An oxide film may be formed on the film, to be polished, of the wafer between a film forming process and a polishing process for the wafer. This oxide film is formed by a reaction of the film formed in the film forming process with oxygen in the air. The oxide film has properties different from those of the films forming the multilayered structure of the wafer. Such oxide film is removed by polishing of the wafer, and then a film underlying the oxide film in the multilayered structure is subsequently polished.

A temperature of the polishing surface of the polishing pad for optimal polishing may vary depending on a condition of the film. Therefore, in order to achieve the optimum polishing rate of the film, it is necessary to control the temperature of the polishing surface of the polishing pad at the optimal temperature during polishing of the wafer. Furthermore, immediately before a polishing end point of the wafer, the temperature of the polishing surface of the polishing pad may be lowered to intendedly lower the polishing rate of the wafer in order to prevent excessive etching or erosion for the wafer. Thus, during polishing of the wafer, it is required to control the temperature of the polishing surface of the polishing pad at the optimal temperature depending on the condition of the film on the wafer.

### SUMMARY

There is provided a technique that can appropriately control a temperature of a polishing surface of a polishing pad during polishing of a workpiece, such as a wafer, according to a condition of a film of the workpiece.

Embodiments, which will be described below, relate to a technique of polishing a workpiece on a polishing surface of a polishing pad while controlling a temperature of the polishing surface.

In an embodiment, there is provided a polishing method comprising: detecting a surface condition of a sample by a surface-condition detector while polishing the sample on a polishing surface of a polishing pad; creating time-series data representing temporal change in the surface condition of the sample; determining a point in time at which the surface condition of the sample has distinctively changed based on the time-series data; determining a temperature control time based on the determined point in time; and controlling a temperature of the polishing surface of the polishing pad based on the temperature control time by a pad-temperature regulating device, while polishing a workpiece on the polishing surface of the polishing pad.

In an embodiment, the surface-condition detector comprises a torque measuring device configured to measure a torque for rotating the polishing pad.

In an embodiment, the surface-condition detector comprises a film-thickness measuring device configured to measure a film thickness of the sample.

In an embodiment, determining the point in time at which the surface condition of the sample has distinctively changed based on the time-series data comprises: creating time-series differential data by performing a differential process on the time-series data; determining a distinctive change point on the time-series differential data; and determining a point in time at which the distinctive change point has appeared on the time-series differential data.

In an embodiment, the differential process comprises a second-order differential process.

In an embodiment, there is provided a polishing apparatus comprising: a polishing table configured to support a polishing pad; a polishing head configured to press a sample and a workpiece against a polishing surface of the polishing pad to polish the sample and the workpiece; a surface-condition detector configured to detect a surface condition of the sample when the sample is polished on the polishing surface of the polishing pad; a pad-temperature regulating device configured to regulate a temperature of the polishing surface of the polishing pad; and an operation controller configured to control an operation of the pad-temperature regulating device, wherein the operation controller is configured to: create time-series data representing temporal change in the surface condition of the sample detected by the surface-condition detector; determine a point in time at which the surface condition of the sample has distinctively changed based on the time-series data; determine a temperature control time based on the determined point in time; and instruct the pad-temperature regulating device to control the temperature of the polishing surface of the polishing pad based on the temperature control time when the workpiece is polished on the polishing surface of the polishing pad.

In an embodiment, the surface-condition detector comprises a torque measuring device configured to measure a torque for rotating the polishing pad.

In an embodiment, the surface-condition detector comprises a film-thickness measuring device configured to measure a film thickness of the sample.

In an embodiment, the operation controller is configured to: create time-series differential data by performing a differential process on the time-series data; determine a distinctive change point on the time-series differential data; and determine a point in time at which the distinctive change point has appeared on the time-series differential data.

In an embodiment, the differential process comprises a second-order differential process.

In an embodiment, there is provided a computer-readable storage medium storing a temperature regulation program for causing a computer to perform the steps of: creating time-series data representing temporal change in a surface condition of a sample detected by a surface-condition detector while the sample is polished on a polishing surface of a polishing pad; determining a point in time at which the surface condition of the sample has distinctively changed based on the time-series data; determining a temperature control time based on the determined point in time; and instructing a pad-temperature regulating device to control a temperature of the polishing surface of the polishing pad based on the temperature control time when a workpiece is polished on the polishing surface of the polishing pad.

In an embodiment, determining the point in time at which the surface condition of the sample has distinctively changed based on the time-series data comprises: creating time-series differential data by performing a differential process on the time-series data; determining a distinctive change point on the time-series differential data; and determining a time point at which the distinctive change point has appeared on the time-series differential data.

In an embodiment, the differential process comprises a second-order differential process.

According to the above-described embodiments, during polishing of the workpiece, the temperature of the polishing surface of the polishing pad can be appropriately controlled according to the condition of the film of the workpiece.

### BRIEF DESCRIPTION OF THE DRAWINGS

FIG. 1 is a schematic diagram showing an embodiment of a polishing apparatus;

FIG. 2 is a flowchart illustrating an embodiment of a polishing method;

FIG. 3 is a graph showing an example of time-series data representing temporal change in a surface condition of a sample;

FIG. 4 is a graph showing an example of time-series first-order differential data created by performing a first-order differential process on the time-series data shown in FIG. 3;

FIG. 5 is a graph showing an example of time-series second-order differential data created by performing a second-order differential process on the time-series data shown in FIG. 3;

FIG. 6 is a diagram showing an example of a multilayered structure of the sample that changes as the sample is polished;

FIG. 7 is a diagram showing an example of a pad-temperature recipe, and an example of a graph showing change in temperature of a polishing surface of a polishing pad according to the pad-temperature recipe;

FIG. 8 is a diagram showing another example of the pad-temperature recipe, and another example of the graph showing change in temperature of the polishing surface of the polishing pad according to the pad-temperature recipe;

FIG. 9 is a graph showing an example of the time-series data, the time-series first-order differential data, and the time-series second-order differential data when a film-thickness measuring device is used as a surface-condition detector; and

FIG. 10 is a diagram showing an example of the multilayered structure of the sample that changes as the sample is polished.

### DESCRIPTION OF EMBODIMENTS

Embodiments will now be described with reference to the drawings.

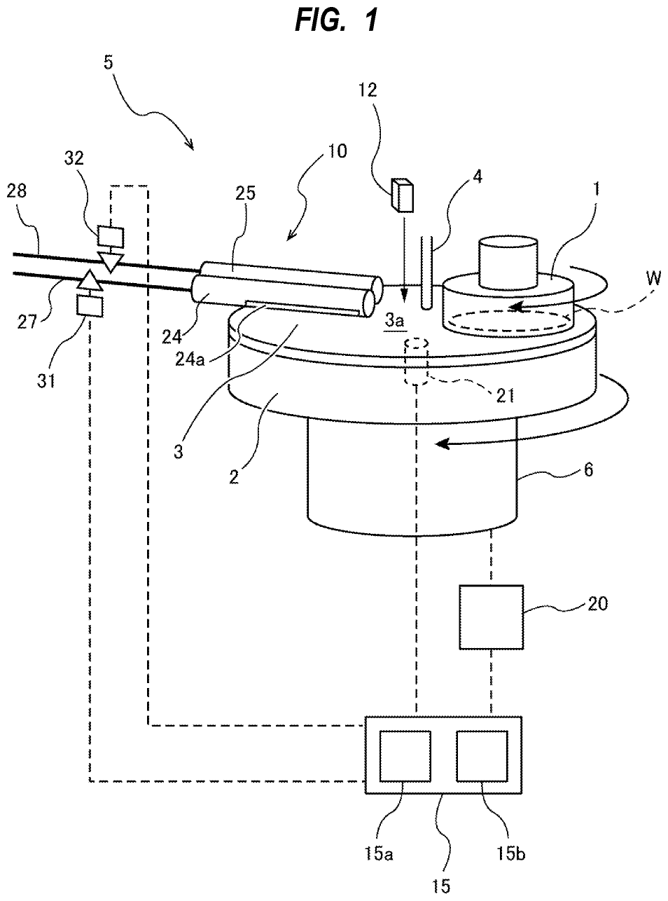

FIG. 1 is a schematic diagram showing an embodiment of a polishing apparatus. The polishing apparatus includes a polishing table 2 configured to support a polishing pad 3, a polishing head 1 configured to press a wafer W, which is an example of a workpiece, against the polishing pad 3, a table-rotating motor 6 configured to rotate the polishing table 2, a polishing-liquid supply nozzle 4 configured to supply a polishing liquid (e.g., slurry containing abrasive grains) onto the polishing pad 3, and a temperature regulating system 5 configured to regulate a temperature of a polishing surface 3a of the polishing pad 3. A surface (i.e., an upper surface) of the polishing pad 3 provides the polishing surface 3a for polishing the wafer W.

Specific examples of the workpiece include a wafer, an interconnect substrate, a quadrangular substrate, etc., for use in manufacturing of semiconductor devices. The workpiece has a multilayered structure including a plurality of films. A surface of the wafer W in embodiments described below is an exposed surface of the multilayered structure including the plurality of films.

The temperature regulating system 5 includes a pad-temperature regulating device 10 configured to regulate the temperature of the polishing surface 3a of the polishing pad 3, a pad-temperature measuring device 12 configured to measure the temperature of the polishing surface 3a of the polishing pad 3, and an operation controller 15 configured to control operations of the pad-temperature regulating device 10. In this embodiment, the operation controller 15 is configured to control operations of the entire polishing apparatus including the temperature regulating system 5.

The operation controller 15 includes a memory 15a storing programs therein, and an arithmetic device 15b configured to perform arithmetic operations according to instructions contained in the programs. The operation controller 15 is composed of at least one computer. The memory 15a includes a main memory, such as a random-access memory (RAM), and an auxiliary memory, such as a hard disk drive (HDD) or a solid state drive (SSD). Examples of the arithmetic device 15b include a CPU (central processing unit) and a GPU (graphic processing unit). However, the specific configuration of the operation controller 15 is not limited to these examples.

The polishing head 1 is vertically movable, and is rotatable about its own axis in a direction indicated by an arrow. The polishing head 1 is coupled to a polishing-head rotating motor (not shown), and is rotatable in a direction indicated by an arrow. As shown in FIG. 1, the polishing head 1 and the polishing table 2 rotate in the same direction. The polishing pad 3 is attached to an upper surface of the polishing table 2.

Polishing of the wafer W is performed as follows. The wafer W to be polished is rotated by the polishing head 1, while the polishing pad 3 is rotated together with the polishing table 2 by the table-rotating motor 6. In this state, the polishing liquid is supplied from the polishing-liquid supply nozzle 4 onto the polishing surface 3a of the polishing pad 3, and the surface of the wafer W is then pressed against the polishing surface 3a of the polishing pad 3 by the polishing head 1. The surface of the wafer W is planarized by a chemical action of the polishing liquid and mechanical action(s) of the abrasive grains contained in the polishing liquid and/or the polishing pad 3.

The temperature regulating system 5 includes a torque measuring device 20 as a surface-condition detector configured to detect a surface condition of the wafer W. The torque measuring device 20 is configured to measure a torque for rotating the polishing pad 3 and the polishing table 2. The torque measuring device 20 is electrically coupled to the operation controller 15. The condition of the surface of the wafer W detected by the torque measuring device 20 is a condition of the surface to be polished of the wafer W. Examples of the condition of the surface of the wafer W include an asperity of the surface of the wafer W, a type and a thickness (or an amount) of the film constituting the surface of the wafer W, and the like. The torque measuring device 20 is configured to output a detection signal that varies depending on the condition of the surface of the wafer W. The detection signal is transmitted to the operation controller 15.

The torque measuring device 20 as the surface-condition detector is electrically coupled to the table-rotating motor 6. The torque measuring device 20 is configured to measure a current to be supplied to the table-rotating motor 6 for rotating the polishing table 2, and transmit the detection signal indicating a measurement value of the current to the operation controller 15.

When an upper film constituting the surface of the wafer W is removed by polishing, a lower film under the upper film is exposed. Since the upper film and the lower film are made of different materials, a friction between the wafer W and the polishing pad 3 changes as the upper film is removed. This change in friction invokes a change in the current to be applied to the table-rotating motor 6. For example, when the film constituting the surface of the wafer W is removed (i.e., when the surface condition of the wafer W changes), the friction increases. As a result, the current to be applied to the table-rotating motor 6 to generate a torque, which is required to rotate the polishing table 2 at a preset speed, increases. Therefore, the torque measuring device 20 as the surface-condition detector can detect the surface condition of the wafer W based on the current that changes according to the torque required to rotate the polishing table 2 at the preset speed.

The torque measuring device 20 of this embodiment that measures the current to be applied to the table-rotating motor 6 indirectly measures the torque for rotating the polishing pad 3 and the polishing table 2, while in one embodiment, the torque measuring device 20 may be configured to directly measure the torque for rotating the polishing pad 3 and the polishing table 2.

In one embodiment, a film-thickness measuring device 21 configured to measure a film thickness of the wafer W may be used as the surface-condition detector that detects the surface condition of the wafer W. The film-thickness measuring device 21 is disposed in the polishing table 2. The film-thickness measuring device 21 is configured to measure the film thickness of the wafer W on the polishing surface 3a of the polishing pad 3 while rotating together with the polishing table 2 and the polishing pad 3. Examples of the film-thickness measuring device 21 include an optical film-thickness measuring device configured to measure the film thickness of the wafer W based on a spectrum of reflected light from the wafer W, and an eddy-current film-thickness measuring device configured to measure the film thickness of the wafer W based on an eddy current generated in the film of the wafer W.

The thickness of the film constituting the surface of the wafer W decreases as the wafer W is polished. Therefore, the film-thickness measuring device 21 as the surface-condition detector can detect the surface condition of the wafer W based on the film thickness of the wafer W. The film-thickness measuring device 21 as the surface-condition detector is configured to transmit a detection signal indicating the film thickness of the wafer W to the operation controller 15. The detection signal indicating the film thickness of the wafer W directly or indirectly represents the film thickness of the wafer W, and varies depending on the film thickness of the wafer W.

The pad-temperature regulating device 10 includes a pad heating device 24 configured to heat the polishing surface 3a of the polishing pad 3, and a pad cooling device 25 configured to cool the polishing surface 3a of the polishing pad 3. The pad heating device 24 and the pad cooling device 25 are located above the polishing table 2 and the polishing pad 3, and are disposed so as to face the polishing surface 3a of the polishing pad 3. The pad heating device 24 and the pad cooling device 25 are not in contact with the polishing surface 3a of the polishing pad 3. The pad-temperature regulating device 10 further includes a heating-fluid supply line 27 configured to supply a heating fluid to the pad heating device 24, a heating-fluid flow-rate control valve 31 configured to regulate a flow rate of the heating fluid flowing through the heating-fluid supply line 27, a cooling-fluid supply line 28 configured to supply a cooling fluid to the pad cooling device 25, and a cooling-fluid flow-rate control valve 32 configured to regulate a flow rate of the cooling fluid flowing through the cooling-fluid supply line 28.

The heating-fluid flow-rate control valve 31 and the cooling-fluid flow-rate control valve 32 are electrically coupled to the operation controller 15, and operations of the heating-fluid flow-rate control valve 31 and the cooling-fluid flow-rate control valve 32 (i.e., the flow rate of the heating fluid flowing through the heating-fluid supply line 27 and the flow rate of the cooling fluid flowing through the cooling-fluid supply line 28) are controlled by the operation controller 15.

The heating fluid is emitted from an ejection port 24a of the pad heating device 24 onto the polishing surface 3a of the polishing pad 3, so that the temperature of the polishing surface 3a of the polishing pad 3 is increased. The cooling fluid is emitted from an ejection port (not shown) of the pad cooling device 25 onto the polishing surface 3a of the polishing pad 3, so that the temperature of the polishing surface 3a of the polishing pad 3 is decreased. The operation controller 15 operates the heating-fluid flow-rate control valve 31 and the cooling-fluid flow-rate control valve 32 to regulate the flow rates of the heating fluid and the cooling fluid to be supplied from the pad heating device 24 and the pad cooling device 25 onto the polishing surface 3a of the polishing pad 3, so that the temperature of the polishing surface 3a of the polishing pad 3 can be controlled.

The pad-temperature measuring device 12 measures the temperature of the polishing surface 3a of polishing pad 3 in a non-contact manner, and transmits the measurement value of the temperature of the polishing surface 3a to the operation controller 15. Examples of the pad-temperature measuring device 12 include an infrared radiation thermometer, a thermocouple thermometer, and the like. The operation controller 15 operates the heating-fluid flow-rate control valve 31 and the cooling-fluid flow-rate control valve 32 based on the measurement value of the temperature such that the temperature of the polishing surface 3a of the polishing pad 3 reaches a preset target temperature.

In one embodiment, the heating fluid is steam. Examples of the steam include water vapor generated by evaporating water, and superheated vapor generated by further heating saturated vapor. In another embodiment, the heating fluid may be a hot gas (e.g., hot air, hot nitrogen gas, or hot argon gas).

In one embodiment, the cooling fluid is a room-temperature gas (e.g., an inert gas, such as nitrogen gas, or argon gas). However, the cooling fluid is not limited to this example. The cooling fluid may be a gas that has been cooled to a temperature lower than a room temperature, or may be a gas having a temperature lower than the target temperature of the polishing surface 3a of the polishing pad 3.

Although not shown in the drawings, in one embodiment, the pad-temperature regulating device 10 may further include a suction nozzle arranged adjacent to the pad cooling device 25. The suction nozzle has a suction port facing the polishing surface 3a of the polishing pad 3. The suction nozzle is coupled to a vacuum source, such as a vacuum pump. When an amount of air sucked through the suction nozzle is increased or decreased, an amount of vaporization heat removed from the polishing liquid on the polishing surface 3a changes. As a result, the temperature of the polishing surface 3a can be regulated.

The pad-temperature regulating device 10 of the embodiment with reference to FIG. 1 is configured to bring the heating fluid and the cooling fluid into direct contact with the polishing surface 3a of the polishing pad 3, while the configuration of the pad-temperature regulating device 10 is not limited to the above-described embodiment as long as the pad-temperature regulating device 10 can regulate the temperature of the polishing pad 3. For example, the pad-temperature regulating device 10 may be configured to pass the heating fluid and the cooling fluid through a heat exchanger disposed so as to face the polishing surface 3a of the polishing pad 3 to perform heat exchange between the heating fluid and the polishing pad 3 via a bottom of the heat exchanger and perform heat exchange between the cooling fluid and the polishing pad 3 via the bottom of the heat exchanger, while the flow rates of the heating fluid and the cooling fluid are regulated.

Next, an embodiment of a polishing method will be described.

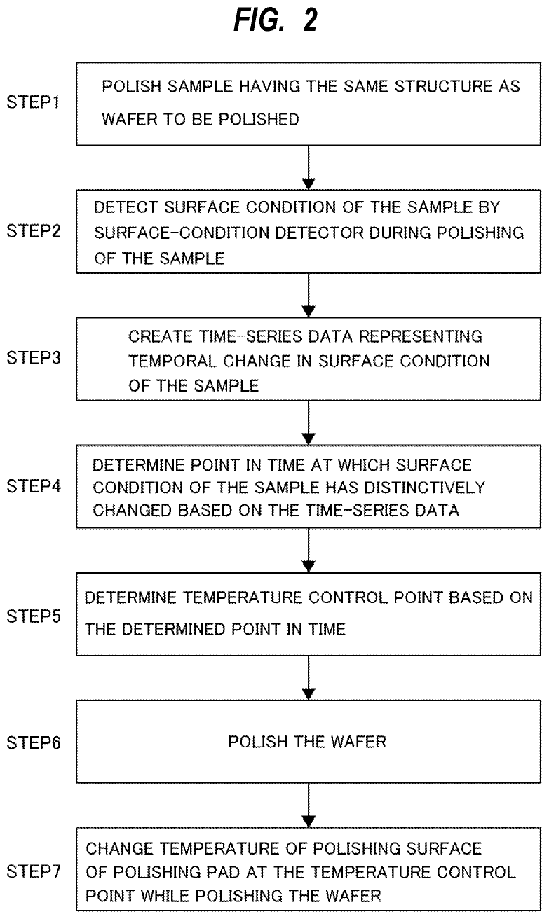

FIG. 2 is a flowchart illustrating an embodiment of the polishing method.

In step 1, the polishing apparatus polishes a sample having the same structure as the wafer W which is a polishing object before polishing the wafer W.

In step 2, a surface condition of the sample is detected by the torque measuring device 20 or the film-thickness measuring device 21 as the surface-condition detector while the sample is polished on the polishing surface 3a of the polishing pad 3.

In step 3, the operation controller 15 creates time-series data representing temporal change in the surface condition of the sample during polishing of the sample.

In step 4, the operation controller 15 determines a point in time at which the surface condition of the sample has distinctively changed based on the time-series data.

In step 5, the operation controller 15 determines a temperature control time at which the temperature of the polishing surface 3a of the polishing pad 3 is to be changed during polishing of the wafer W based on the point in time determined in the step 4.

In step 6, the polishing apparatus polishes the wafer W.

In step 7, the operation controller 15 instructs the pad-temperature regulating device 10 to control the temperature of the polishing surface 3a of the polishing pad 3 based on the temperature control time, while the polishing apparatus polishes the wafer W on the polishing surface 3a of the polishing pad 3.

The operation controller 15 operates according to the instructions contained in the programs electrically stored in the memory 15a to perform the steps 1 to 7. The programs for causing the operation controller 15 to perform these steps are stored in a non-transitory tangible computer-readable storage medium, and are provided to the operation controller 15 via the storage medium. Alternatively, the programs may be provided to the operation controller 15 via a communication network, such as the Internet or a local area network. The operation controller 15 may be composed of one computer. In another example, the operation controller 15 may be composed of a plurality of computers.

The steps 1 to 7 will be described in detail below.

The step 1 is a process of polishing the sample having the same structure as the wafer W by the polishing apparatus before the wafer W is polished. The sample is a workpiece having the same multilayered structure as the wafer W which is a polishing object. More specifically, the sample has a multilayered structure including a plurality of films which are the same as those of the wafer W to be polished. If the workpiece to be polished is a wafer, the sample is also a wafer. If the workpiece to be polished is a quadrangular substrate, the sample is also a quadrangular substrate. In this embodiment, since the workpiece to be polished is the wafer W, the sample is also a wafer having the same multilayered structure as the wafer W.

The polishing of the sample is performed in the same manner as the polishing of the wafer W. Specifically, the sample is rotated by the polishing head 1, while the polishing pad 3 is rotated together with the polishing table 2 by the table-rotating motor 6. The polishing liquid is supplied from the polishing-liquid supply nozzle 4 onto the polishing surface 3a of the polishing pad 3, and the surface of the sample is then pressed against the polishing surface 3a of the polishing pad 3 by the polishing head 1.

The sample is polished under the same polishing conditions as those for the wafer W. The polishing conditions include a type and a flow rate of the polishing liquid for use in polishing, a rotation speed of the polishing table 2 and the polishing pad 3, a rotation speed of the polishing head 1, a pressing force of the polishing head 1 on the polishing pad 3, and the like.

The step 2 is a process of detecting the surface condition of the sample by the torque measuring device 20 or the film-thickness measuring device 21 as the surface-condition detector while the sample is being polished on the polishing surface 3a of the polishing pad 3. In an embodiment in which the surface-condition detector is the torque measuring device 20, the torque measuring device 20 measures a torque current to be supplied to the table-rotating motor 6 during polishing of the sample, and transmits a detection signal indicating the measurement value of the torque current to the operation controller 15. In an embodiment in which the surface-condition detector is the film-thickness measuring device 21, the film-thickness measuring device 21 measures a film thickness of the sample during polishing of the sample, and transmits a detection signal indicating the film thickness of the sample to the operation controller 15.

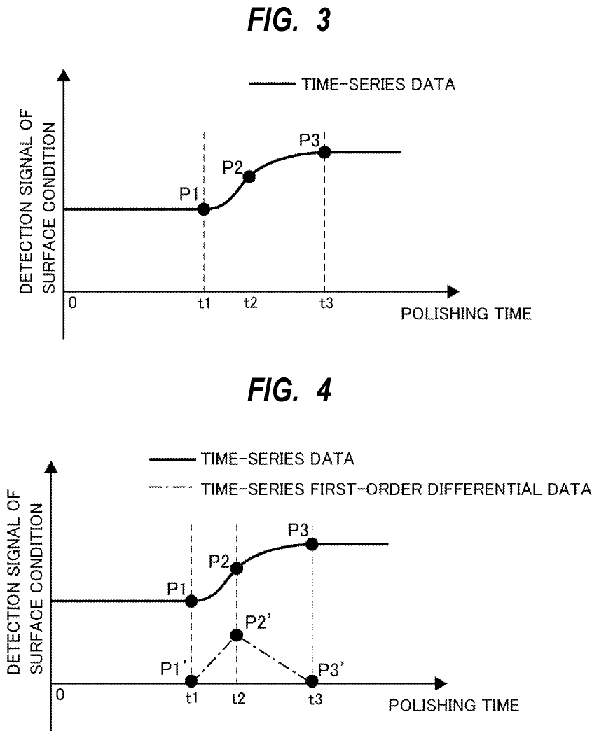

The step 3 is a process of creating the time-series data representing temporal change in the surface condition of the sample during polishing of the sample. More specifically, the operation controller 15 creates the time-series data as shown in FIG. 3 by receiving detection signals each indicating the surface condition of the sample transmitted from the surface-condition detector (i.e., the torque measuring device 20 or the film-thickness measuring device 21), and arranging the detection signals along polishing time. The created time-series data is stored, for example, in the memory 15a provided in the polishing apparatus. In the example shown in FIG. 3, vertical axis represents detection signal indicating the surface condition of the sample detected by the torque measuring device 20 as the surface-condition detector, and horizontal axis represents polishing time of the sample. The time-series data shown in FIG. 3 indicates temporal change in the detection signal output from the torque measuring device 20. As can be seen from FIG. 3, the time-series data represents the surface condition of the sample that changes with the polishing time.

The step 4 is a process of determining a point in time at which the surface condition of the sample has distinctively changed based on the time-series data. The point in time at which the surface condition of the sample has distinctively changed is a point in time at which a distinctive change point has appeared on the time-series data. In the example shown in FIG. 3, a distinctive change point P1 on the time-series data is a point at which the detection signal indicating the surface condition of the sample begins to rise, a distinctive change point P2 on the time-series data is an inflection point at which the detection signal indicating the surface condition of the sample changes from a rising trend to a decreasing trend, and a distinctive change point P3 on the time-series data is a point at which the detection signal indicating the surface condition of the sample stops rising. The operation controller 15 is configured to determine the points in time at which the surface condition of the sample has distinctively changed, i.e., points in time t1, t2, and t3 at which the distinctive change points P1, P2, and P3 have appeared on the time-series data.

In order to easily detect the distinctive change points P1, P2, and P3 on the time-series data, in one embodiment, as shown in FIG. 4, the operation controller 15 may create time-series differential data by performing a differential process on the time-series data, may determine distinctive change points P1′, P2′, and P3′ on the time-series differential data, and may determine points in time t1, t2, and t3 at which the distinctive change points P1′, P2′, and P3′ have appeared. In the embodiment shown in FIG. 4, the differential process is a first-order differential process. The operation controller 15 creates time-series first-order differential data by performing the first-order differential process on the time-series data shown in FIG. 3. As shown in FIG. 4, the time-series first-order differential data changes linearly, so that the operation controller 15 can easily determine the distinctive change points P1′, P2′, and P3′ on the time-series first-order differential data.

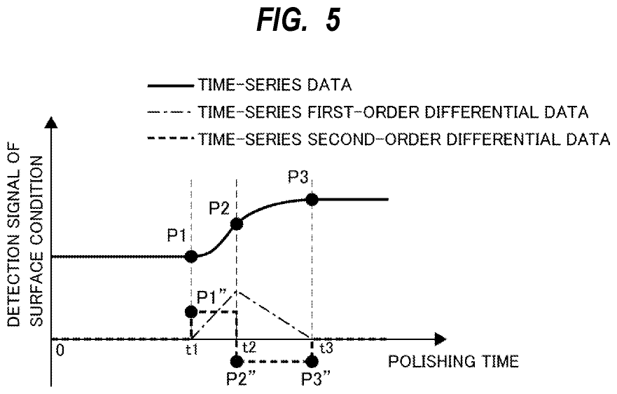

In one embodiment, as shown in FIG. 5, the operation controller 15 may perform a second-order differential process on the time-series data shown in FIG. 3. Specifically, the operation controller 15 may create time-series second-order differential data by further performing a differentiation process on the time-series first-order differential data shown in FIG. 4, may determine distinctive change points P1″, P2″, and P3″ on the time-series second-order differential data, and may determine points in time t1, t2, and t3 at which the distinctive change points P1″, P2″, and P3″ have appeared. As shown in FIG. 5, the time-series second-order differential data changes stepwise, so that the operation controller 15 can easily determine the distinctive change points P1″, P2″, and P3″ on the time-series second-order differential data.

Furthermore, in one embodiment, the operation controller 15 may determine the points in time t1, t2, and t3 at which the surface condition of the sample has distinctively changed based on a combination of the time-series data, the time-series first-order differential data, and the time-series second-order differential data.

The step 5 is a process of determining a plurality of temperature control times based on the points in time t1, t2, and t3 at which the distinctive change points have appeared. Each of the temperature control times may be a point in time at which the distinctive change point itself has appeared, or may be a time obtained by adding a preset delay time to the point in time at which the distinctive change point has appeared. For example, the temperature control times may be the points in time t1 and t2 at which the distinctive change points P1 and P2 (or P1′, P2′, or P1″, P2″) have appeared, and a point in time t3+d obtained by adding a delay time d to the point in time t3 at which the distinctive change point P3 (or P3′, or P3″) has appeared. In other words, examples of determining the temperature control time based on the point in time at which the distinctive change point has appeared include determining the temperature control time at which the distinctive change point has appeared, and determining the temperature control time obtained by adding the delay time to the point in time at which the distinctive change point has appeared. The operation controller 15 stores the determined temperature control times (e.g., t1, t2, and t3+d) into the memory 15a.

The step 6 is a process of polishing the wafer W by the polishing apparatus. The wafer W is rotated by the polishing head 1, while the polishing pad 3 is rotated together with the polishing table 2 by the table-rotating motor 6. The polishing liquid is supplied from the polishing-liquid supply nozzle 4 onto the polishing surface 3a of the polishing pad 3, and the surface of the wafer W is then pressed against the polishing surface 3a of the polishing pad 3 by the polishing head 1.

The step 7 is process of controlling the temperature of the polishing surface 3a of the polishing pad 3 based on the temperature control times determined in the step 5, while the wafer W is being polished on the polishing surface 3a of the polishing pad 3 by the polishing apparatus. More specifically, during polishing of the wafer W, the operation controller 15 instructs the pad-temperature regulating device 10 according to a pad-temperature recipe created in advance to control the temperature of the polishing surface 3a of the polishing pad 3 based on the temperature control times. The pad-temperature recipe is an operation sequence of the pad-temperature regulating device 10 for controlling the temperature of the polishing surface 3a of the polishing pad 3 during polishing of the wafer W based on the temperature control times.

The change in the surface condition of the sample as shown in FIGS. 3 to 5 depend on a change in the multilayered structure constituting the surface of the sample as the sample is polished. Hereinafter, a specific example of a relationship between change in the multilayered structure of the sample as the sample is polished and change in the surface condition of the sample (i.e., the time-series data) will be described.

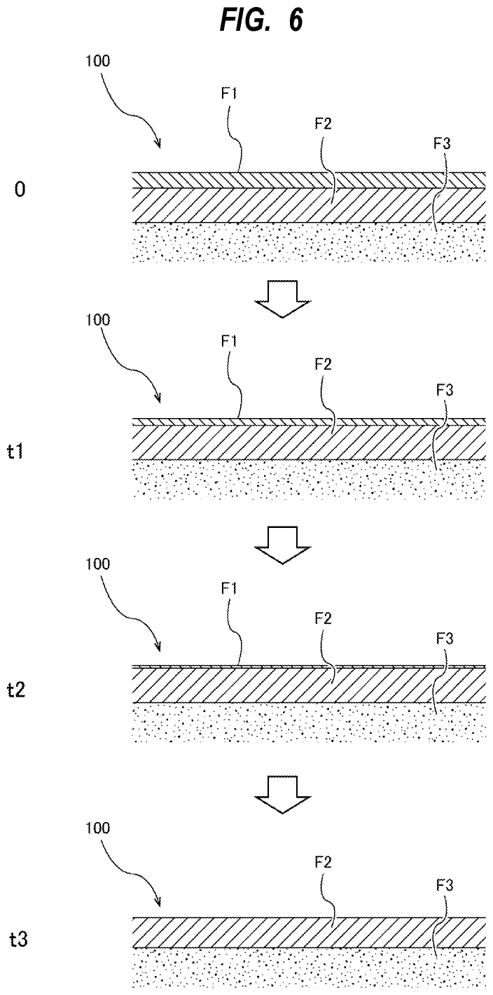

FIG. 6 is a diagram showing an example of the multilayered structure of the sample that changes as the sample is polished. A sample 100 in this example has a multilayered structure including a first film F1, a second film F2, and a base layer F3. The first film F1 is on the second film F2, and the second film F2 is on the base layer F3. Examples of the first film F1 include a film formed by a film forming apparatus (e.g., a plating apparatus, a CVD apparatus, or a PVD apparatus), an oxide film formed by a reaction of a film formed by the film forming apparatus with oxygen in the air, and the like.

Points in time 0, t1, t2, and t3 shown in FIG. 6 correspond to the points in time 0, t1, t2, and t3 shown in FIGS. 3 to 5, respectively.

A period of time from the point in time 0 to the point in time t1 shown in FIG. 6 is a period of time during which the first film F1 is polished. A surface of the sample 100 is constituted of the first film F1.

The point in time t1 shown in FIG. 6 is a point in time at which a thickness of the first film F1 has decreased and the second film F2 begins to be exposed. Most of the surface of the sample 100 is constituted of the first film F1, and a part of the surface of the sample 100 is constituted of the second film F2.

A point in time t2 shown in FIG. 6 is a point in time at which most of the first film F1 has been removed and an exposed area of the first film F1 is smaller than an exposed area of the second film F2. The surface of the sample 100 is constituted of the first film F1 and the second film F2.

A point in time t3 shown in FIG. 6 is a point in time when the first film F1 has been removed. The surface of the sample 100 is constituted of the second film F2.

As described above, the operation controller 15 determines the temperature control times based on the points in time t1, t2, and t3 at which the distinctive change points have appeared. For example, the temperature control times are the points in time t1 and t2 at which the distinctive change points P1 and P2 have appeared, and the point in time t3+d obtained by adding the delay time d to the point in time t3 at which the distinctive change point P3 has appeared. This delay time d is added for the purpose of ensuring that the first film F1 has been removed.

Before polishing of the wafer W in the step 6, the operation controller 15 creates the pad-temperature recipe for use in polishing of the wafer W using the temperature control times determined based on the points in time t1, t2, and t3. The pad-temperature recipe is an operation sequence of the pad-temperature regulating device 10 for controlling the temperature of the polishing surface 3a of the polishing pad 3 based on the temperature control times during polishing of the wafer W.

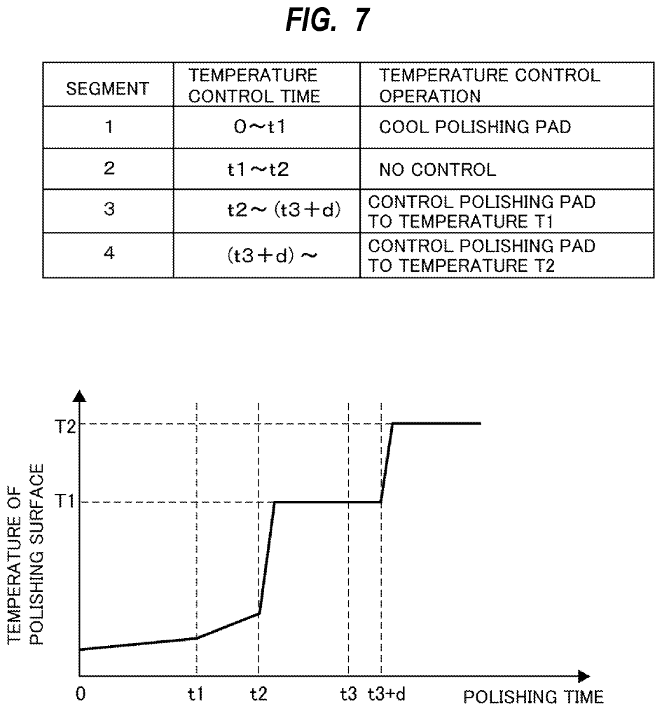

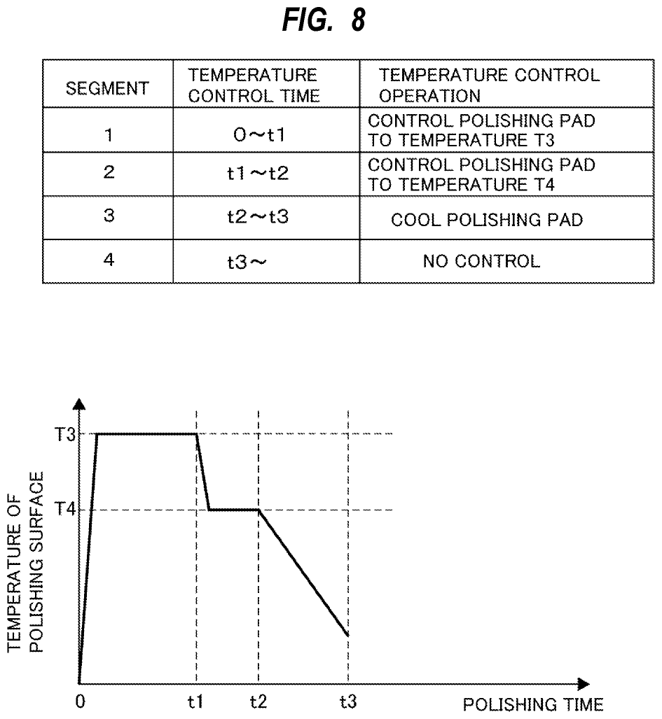

FIG. 7 is a diagram showing an example of the pad-temperature recipe, and an example of a graph showing change in temperature of the polishing surface 3a of the polishing pad 3 according to the pad-temperature recipe. In the example of FIG. 7, the temperature control times determined based on the points in time t1, t2, and t3 obtained by the sample polishing are t1, t2, and t3+d.

Points in time 0, t1, t2, and t3 shown in FIG. 7 correspond to the points in time 0, t1, t2, and t3 shown in FIGS. 3 to 6, respectively.

A segment 1 of the pad-temperature recipe is a period of time from the temperature control time 0 to the temperature control time t1 (see 0 to t1 in FIG. 6). An operation of the pad-temperature regulating device 10 in this segment 1 is to cool the polishing surface 3a of the polishing pad 3.

A segment 2 of the pad-temperature recipe is a period of time from the temperature control time t1 to the temperature control time t2 (see t1 to t2 in FIG. 6). An operation of the pad-temperature regulating device 10 in this segment 2 is not to control the temperature of the polishing surface 3a of the polishing pad 3, i.e., the operation in the segment 2 is neither heating nor cooling the polishing surface 3a of the polishing pad 3. Therefore, during the period of time from the temperature control time t1 to t2, the temperature of the polishing surface 3a of the polishing pad 3 gradually increases due to frictional heat.

A segment 3 of the pad-temperature recipe is a period of time from the temperature control time t2 to the temperature control time (t3+d) (see t2 to t3 in FIG. 6). An operation of the pad-temperature regulating device 10 in this segment 3 is to heat the polishing surface 3a of the polishing pad 3 to a first temperature T1, and then control the temperature of the polishing surface 3a of the polishing pad 3 so as to maintain the first temperature T1.

A segment 4 of the pad-temperature recipe is a period of time after the temperature control time t3+d (see t3 in FIG. 6). An operation of the pad-temperature regulating device 10 in this segment 4 is to heat the polishing surface 3a of the polishing pad 3 to a second temperature T2 higher than the first temperature T1, and then control the temperature of the polishing surface 3a of the polishing pad 3 so as to maintain the second temperature T2.

The pad-temperature recipe created in this way is stored in the memory 15a of the operation controller 15. After the pad-temperature recipe is created, the polishing apparatus polishes the wafer W that is to be originally polished.

During polishing of the wafer W, the operation controller 15 instructs the pad-temperature regulating device 10 according to the pad-temperature recipe to control the temperature of the polishing surface 3a of the polishing pad 3 based on the determined temperature control times. In one example, when the polishing time of the wafer W reaches the temperature control time, the operation controller 15 operates at least one of the heating-fluid flow-rate control valve 31 and the cooling-fluid flow-rate control valve 32 of the pad-temperature regulating device 10 to change the temperature of the polishing surface 3a of the polishing pad 3. In another example, as in the above-described segment 2, when the polishing time of the wafer W reaches the temperature control time, the operation controller 15 closes both the heating-fluid flow-rate control valve 31 and the cooling-fluid flow-rate control valve 32 of the pad-temperature regulating device 10.

During polishing of the wafer W, the operation controller 15 does not monitor the detection signal from the torque measuring device 20 or the film-thickness measuring device 21 as the surface-condition detector, while the operation controller 15 controls the temperature of the polishing surface 3a of the polishing pad 3 based on the polishing time of the wafer W and the temperature control times. A processing time required for detecting the surface condition of the wafer W by the surface-condition detector can be omitted, so that the operation controller 15 can quickly control the temperature of the polishing surface 3a of the polishing pad 3 based on the temperature control times.

FIG. 8 is a diagram showing another example of the pad-temperature recipe, and another example of the graph showing change in temperature of the polishing surface 3a of the polishing pad 3 according to the pad-temperature recipe. In the example of FIG. 8, the temperature control times are the points in time t1, t2, and t3 obtained by the sample polishing. The purpose of the pad-temperature recipe shown in FIG. 8 is to improve a finishing quality of a polished surface of the wafer W by intentionally lowering a polishing rate in a final stage of the polishing of the wafer W.

The points in time 0, t1, t2, and t3 shown in FIG. 8 correspond to the points in time 0, t1, t2, and t3 shown in FIGS. 3 to 6, respectively.

A segment 1 of the pad-temperature recipe is a period of time from the temperature control time 0 to the temperature control time t1 (see 0 to t1 in FIG. 6). An operation of the pad-temperature regulating device 10 in this segment 1 is to heat the polishing surface 3a of the polishing pad 3 to a first temperature T3, and then control the temperature of the polishing surface 3a of the polishing pad 3 so as to maintain the first temperature T3.

A segment 2 of the pad-temperature recipe is a period of time from the temperature control time t1 to the temperature control time t2 (see t1 to t2 in FIG. 6). An operation of the pad-temperature regulating device 10 in this segment 2 is to cool the polishing surface 3a of the polishing pad 3 to a second temperature T4 lower than the first temperature T3, and then control the temperature of the polishing surface 3a of the polishing pad 3 so as to maintain the second temperature T4.

A segment 3 of the pad-temperature recipe is a period of time from the temperature control time t2 to the temperature control time t3 (see t2 to t3 in FIG. 6). An operation of the pad-temperature regulating device 10 in this segment 3 is to cool the polishing surface 3a of the polishing pad 3.

A segment 4 of the pad-temperature recipe is a period of time after the temperature control time t3. An operation of the pad-temperature regulating device 10 in this period 4 is not to control the temperature of the polishing surface 3a of the polishing pad 3, i.e., the operation in the segment 4 is neither heating nor cooling the polishing surface 3a of the polishing pad 3.

According to the pad-temperature recipe in FIG. 8, the temperature of the polishing pad 3 is lowered during the period of time from the temperature control time t2 to the temperature control time t3 (i.e., when the thickness of the first film F1 in FIG. 6 has become small). Therefore, the polishing rate of the first film F1 is reduced, and as a result, the finishing quality of the surface of the wafer W after the first film F1 has been removed can be improved.

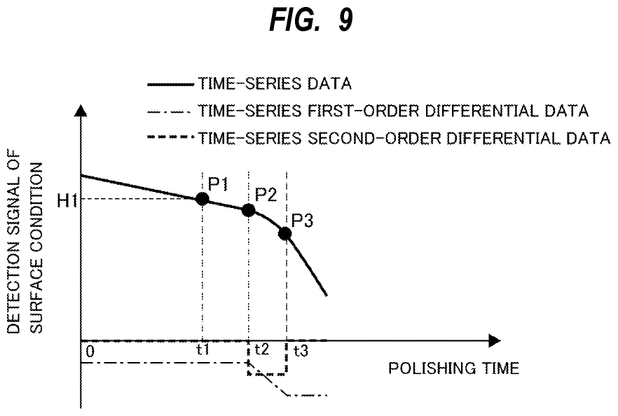

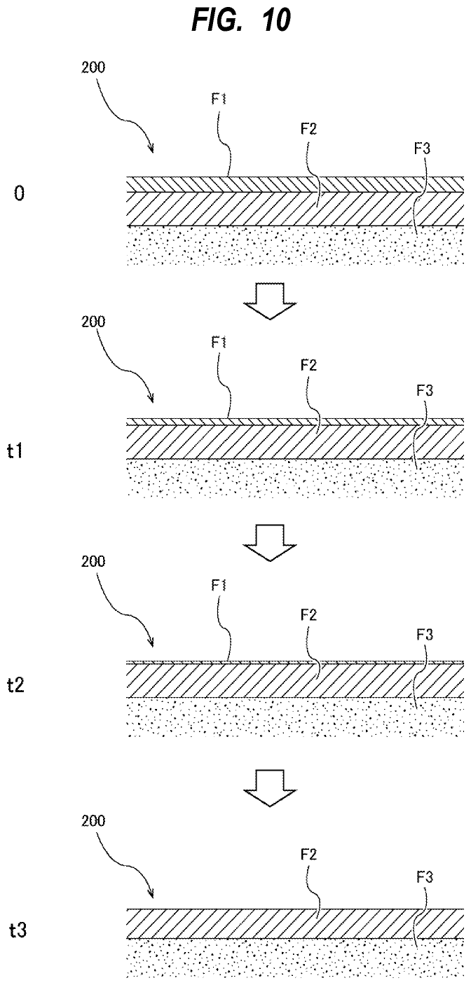

FIG. 9 is a graph showing an example of the time-series data, the time-series first-order differential data, and the time-series second-order differential data when the film-thickness measuring device 21 is used as the surface-condition detector. The operation controller 15 creates time-series data as shown in FIG. 9 by receiving the detection signals each indicating the surface condition of the sample transmitted from the film-thickness measuring device 21 as the surface-condition detector, and arranging the detection signals along the polishing time of the sample. The operation controller 15 may further create time-series first-order differential data and time-series second-order differential data by performing a first-order differential process and a second-order differential process on the time-series data.

In the example shown in FIG. 9, a distinctive change point P1 on the time-series data is a point at which the detection signal indicating the surface condition of the sample reaches a threshold value H1, a distinctive change point P2 on the time-series data is a point at which a rate of decrease in the detection signal indicating the surface condition of the sample begins to decrease, and a distinctive change point P3 on the time-series data is a point at which the rate of decrease in the detection signal indicating the surface condition of the sample stops decreasing.

FIG. 10 is a diagram showing an example of the multilayered structure of the sample that changes as the sample is polished. A sample 200 shown in FIG. 10 has the same structure as the sample 100 shown in FIG. 6.

Points in time 0, t1, t2, and t3 shown in FIG. 10 correspond to 0, t1, t2, and t3 shown in FIG. 9, respectively.

A period of time from the point in time 0 to the point in time t1 shown in FIG. 10 is a period of time during which the first film F1 is polished. A surface of the sample 200 is constituted of the first film F1.

The point in time t1 shown in FIG. 10 is a point in time at which a thickness of the first film F1 has decreased and the second film F2 begins to be exposed. Most of the surface of the sample 200 is constituted of the first film F1, and a part of the surface of the sample 200 is constituted of the second film F2.

A point in time t2 shown in FIG. 10 is a point in time at which most of the first film F1 has been removed and an exposed area of the first film F1 is smaller than an exposed area of the second film F2. The surface of the sample 200 is constituted of the first film F1 and the second film F2.

A point in time t3 shown in FIG. 10 is a point in time when the first film F1 has been removed. The surface of the sample 200 is constituted of the second film F2.

The operation controller 15 determines the points in time t1, t2, and t3 at which the surface condition of the sample has distinctively changed based on any one of the time-series data, the time-series first-order differential data, and the time-series second-order differential data shown in FIG. 9, or a combination thereof, and determines temperature control times based on the determined points in time. Further, the operation controller 15 creates the pad-temperature recipe as shown in FIG. 7 or 8 using the temperature control times. During polishing of the wafer W, the operation controller 15 instructs the pad-temperature regulating device 10 according to the pad-temperature recipe to control the temperature of the polishing surface 3a of the polishing pad 3 based on the determined temperature control times.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

What is claimed is:

1. A polishing method comprising:
detecting a surface condition of a sample by a surface-condition detector while polishing the sample on a polishing surface of a polishing pad;
creating time-series data representing temporal change in the surface condition of the sample;
determining a point in time at which the surface condition of the sample has distinctively changed based on the time-series data;
determining a temperature control time based on the determined point in time; and
controlling a temperature of the polishing surface of the polishing pad based on the temperature control time by a pad-temperature regulating device, while polishing a workpiece on the polishing surface of the polishing pad.

2. The polishing method according to claim 1, wherein the surface-condition detector comprises a torque measuring device configured to measure a torque for rotating the polishing pad.

3. The polishing method according to claim 1, wherein the surface-condition detector comprises a film-thickness measuring device configured to measure a film thickness of the sample.

4. The polishing method according to claim 1, wherein determining the point in time at which the surface condition of the sample has distinctively changed based on the time-series data comprises:
creating time-series differential data by performing a differential process on the time-series data;
determining a distinctive change point on the time-series differential data; and
determining a point in time at which the distinctive change point has appeared on the time-series differential data.

5. The polishing method according to claim 4, wherein the differential process comprises a second-order differential process.

6. A polishing apparatus comprising:
a polishing table configured to support a polishing pad;
a polishing head configured to press a sample and a workpiece against a polishing surface of the polishing pad to polish the sample and the workpiece;
a surface-condition detector configured to detect a surface condition of the sample when the sample is polished on the polishing surface of the polishing pad;
a pad-temperature regulating device configured to regulate a temperature of the polishing surface of the polishing pad; and
an operation controller configured to control an operation of the pad-temperature regulating device,
wherein the operation controller is configured to:
create time-series data representing temporal change in the surface condition of the sample detected by the surface-condition detector;
determine a point in time at which the surface condition of the sample has distinctively changed based on the time-series data;
determine a temperature control time based on the determined point in time; and
instruct the pad-temperature regulating device to control the temperature of the polishing surface of the polishing pad based on the temperature control time when the workpiece is polished on the polishing surface of the polishing pad.

7. The polishing apparatus according to claim 6, wherein the surface-condition detector comprises a torque measuring device configured to measure a torque for rotating the polishing pad.

8. The polishing apparatus according to claim 6, wherein the surface-condition detector comprises a film-thickness measuring device configured to measure a film thickness of the sample.

9. The polishing apparatus according to claim 6, wherein the operation controller is configured to:
create time-series differential data by performing a differential process on the time-series data;
determine a distinctive change point on the time-series differential data; and
determine a point in time at which the distinctive change point has appeared on the time-series differential data.

10. The polishing apparatus according to claim 6, wherein the differential process comprises a second-order differential process.

11. A computer-readable storage medium storing a temperature regulation program for causing a computer to perform the steps of:
creating time-series data representing temporal change in a surface condition of a sample detected by a surface-condition detector while the sample is polished on a polishing surface of a polishing pad;
determining a point in time at which the surface condition of the sample has distinctively changed based on the time-series data;
determining a temperature control time based on the determined point in time; and
instructing a pad-temperature regulating device to control a temperature of the polishing surface of the polishing pad based on the temperature control time when a workpiece is polished on the polishing surface of the polishing pad.

12. The computer-readable storage medium storing the temperature regulation program according to claim 11, wherein determining the point in time at which the surface condition of the sample has distinctively changed based on the time-series data comprises:
creating time-series differential data by performing a differential process on the time-series data;
determining a distinctive change point on the time-series differential data; and
determining a time point at which the distinctive change point has appeared on the time-series differential data.

13. The computer-readable storage medium storing the temperature regulation program according to claim 11, wherein the differential process comprises a second-order differential process.
